(19) United States
(12) Patent Application Publication
(10) Pub. No.: US 2025/0344410 A1
(43) Pub. Date: Nov. 6, 2025

(54) MULTI-LEVEL RESISTIVE RANDOM ACCESS MEMORY (RRAM) CELLS

(71) Applicant: Silicon Storage Technology, Inc., San Jose, CA (US)

(72) Inventors: Yi Song, San Jose, CA (US); Xian Liu, Sunnyvale, CA (US); Feng Zhou, Fremont, CA (US)

(21) Appl. No.: 18/815,756

(22) Filed: Aug. 26, 2024

Related U.S. Application Data
(60) Provisional application No. 63/643,233, filed on May 6, 2024.

(51) Int. Cl. H10B 63/00

(52) U.S. Cl. CPC H10B 63/82; H10B 63/30

(57) ABSTRACT

An RRAM memory cell comprising a lower electrode disposed over a semiconductor substrate, a first block of resistive switching dielectric material electrically connected to the lower electrode, a second block of resistive switching dielectric material electrically connected to the lower electrode, a first upper electrode electrically connected to the first block of resistive switching dielectric material, a second upper electrode electrically connected to the second block of resistive switching dielectric material, a first resistive contact electrically connected between the first upper electrode and an electrical contact, and a second resistive contact electrically connected between the second upper electrode and the electrical contact. The first resistive contact has a first electrical resistance between the first upper electrode and the electrical contact, and the second resistive contact has a second electrical resistance between the second upper electrode and the electrical contact. The first electrical resistance is different from the second electrical resistance.

### RELATED APPLICATIONS

This application claims the benefit of U.S. Provisional Application No. 63/643,233, filed May 6, 2024, and which is incorporated herein by reference.

### FIELD OF THE INVENTION

The present invention relates to non-volatile memory, and more specifically to resistive random access memory.

### BACKGROUND OF THE INVENTION

Resistive random access memory (RRAM) is a type of nonvolatile memory. Generally, RRAM memory cells each include a resistive switching dielectric material layer sandwiched between two conductive electrodes. The resistive switching dielectric material is normally insulating. However, by applying the proper voltage across the resistive switching dielectric material layer, a conduction path (typically referred to as a filament) can be formed through the resistive switching dielectric material layer resulting in a lower resistance across the RRAM cell. Once the filament is formed, it can be “reset” (i.e., broken or ruptured, resulting in a high resistance across the RRAM cell) and set (i.e., re-formed, again resulting in a lower resistance across the RRAM cell), by applying the appropriate voltages across the resistive switching dielectric material layer. The low and high resistance states can be utilized to indicate a digital state of “1” or “0” depending upon the resistance state, and thereby provide a reprogrammable non-volatile memory cell that can be programmed to one of two possible program states to store one bit of information.

FIG. 1 shows a conventional configuration of an RRAM memory cell 1. The memory cell 1 includes a resistive device 2 having a resistive switching dielectric material layer 4 sandwiched between two conductive material layers that form upper electrode 6 and lower electrode 8. The resistive device 2 is connected in series with a transistor 10, having a source region 12 and drain region 14 formed in a semiconductor substrate 16, and a gate 18. Conductive contacts 20 are formed in insulation material 22 covering the transistor 10. A bit line contact 24 is electrically connected to the upper electrode 24. One of the contacts 20 electrically connects the lower electrode 8 to the drain region 14. The other contact 20 electrically connects the source region 12 to a source line contact 26. The transistor 10 is used to select and operate the resistive device 2.

FIGS. 2A-2D show the switching mechanism of the resistive switching dielectric material layer 4. Specifically, FIG. 2A shows the resistive switching dielectric material layer 4 in its initial state after fabrication, where the layer 4 exhibits a relatively high resistance. FIG. 2B shows the formation of a conductive filament 4a through the layer 4 by applying the appropriate voltage across the layer 4. The filament 4a is a conductive path through the layer 4, such that the layer 4 exhibits a relatively low resistance across it between the upper and lower electrodes (because of the relatively high conductivity of the filament 4a). FIG. 2C shows the formation of a rupture 4b in filament 4a caused by the application of a “reset” voltage across the layer 4. The area of the rupture 4b has a relatively high resistance, so that layer 4 exhibits a relatively high resistance across it. FIG. 2D shows the restoration of the filament 4a in the area of the rupture 4b caused by the application of a “set” voltage across layer 4. The restored filament 4a means the layer 4 exhibits a relatively low resistance across it. The relatively low resistance of layer 4 in the “formed” or “set” states of FIGS. 2B and 2D respectively can represent a digital state (e.g. a “1”), and the relatively high resistance of layer 4 in the “reset” state of FIG. 2C can represent a different digital state (e.g. a “0”). The reset voltage (which breaks the filament 4a) can have a polarity opposite that of the filament formation and the set voltages, but it can also have the same polarity. The RRAM cell 1 can repeatedly be “reset” and “set,” so it forms a reprogrammable nonvolatile memory cell for storing one bit of information (“0” or “1) represented by two possible program states.

There are applications, such as neural net applications, where there is a need for multi-bit memory (i.e., multi-level memory where the memory cells can have more than just two possible program states and therefore store more than just 1's or 0's). There is also a need to scale down the size of the RRAM memory cell.

### BRIEF SUMMARY OF THE INVENTION

The aforementioned problems and needs are addressed by an RRAM memory cell comprising a semiconductor substrate, a lower electrode disposed over the semiconductor substrate, a first block of resistive switching dielectric material electrically connected to the lower electrode, a second block of resistive switching dielectric material electrically connected to the lower electrode, a first upper electrode electrically connected to the first block of resistive switching dielectric material, a second upper electrode electrically connected to the second block of resistive switching dielectric material, an electrical contact, a first resistive contact electrically connected between the first upper electrode and the electrical contact, and a second resistive contact electrically connected between the second upper electrode and the electrical contact. The first resistive contact has a first electrical resistance between the first upper electrode and the electrical contact, and the second resistive contact has a second electrical resistance between the second upper electrode and the electrical contact, and the first electrical resistance is different from the second electrical resistance.

A method of forming a RRAM memory cell comprises forming a transistor on a semiconductor substrate, forming a lower electrode disposed over the semiconductor substrate, forming a first block of resistive switching dielectric material electrically that is connected to the lower electrode, forming a second block of resistive switching dielectric material that is electrically connected to the lower electrode, forming a first upper electrode that is electrically connected to the first block of resistive switching dielectric material, forming a second upper electrode that is electrically connected to the second block of resistive switching dielectric material, forming an electrical contact, forming a first resistive contact that is electrically connected between the first upper electrode and the electrical contact, and forming a second resistive contact that is electrically connected between the second upper electrode and the electrical contact. The first resistive contact has a first electrical resistance between the first upper electrode and the electrical contact, and the second resistive contact has a second electrical resistance between the second upper electrode and the electrical contact, and the first electrical resistance is different from the second electrical resistance.

Other objects and features of the present disclosure will become apparent by a review of the specification, claims and appended figures.

### BRIEF DESCRIPTION OF THE DRAWINGS

FIG. 1 is a side cross sectional view of a conventional RRAM memory cell.

FIG. 2A is a side cross sectional view of a conventional RRAM memory cell resistive switching dielectric material layer in its initial state.

FIG. 2B is a side cross sectional view of a conventional RRAM memory cell resistive switching dielectric material layer illustrating the formation of a conductive filament.

FIG. 2C is a side cross sectional view of a conventional RRAM memory cell resistive switching dielectric material layer illustrating the formation of a rupture in the conductive filament.

FIG. 2D is a side cross sectional view of a conventional RRAM memory cell resistive switching dielectric material layer illustrating the restoration of the conductive filament in the area of the rupture.

FIG. 3 is a side cross section view of a RRAM memory cell.

FIG. 4 is a schematic diagram of the RRAM memory cell of FIG. 3.

FIG. 5 is a table showing the possible resistive state combinations for the RRAM memory cell of FIG. 3.

FIGS. 6-7 are tables showing operational voltages for the RRAM memory cell of FIG. 3.

FIG. 8 is a table showing numerical examples of resistances and read currents for the RRAM memory cell.

FIG. 9 is a table of numerical examples of the operational voltages for the RRAM memory cell of FIG. 3.

FIG. 10 is a side cross section view of another example of the RRAM memory cell.

FIG. 11 is a schematic diagram of the RRAM memory cell of FIG. 10.

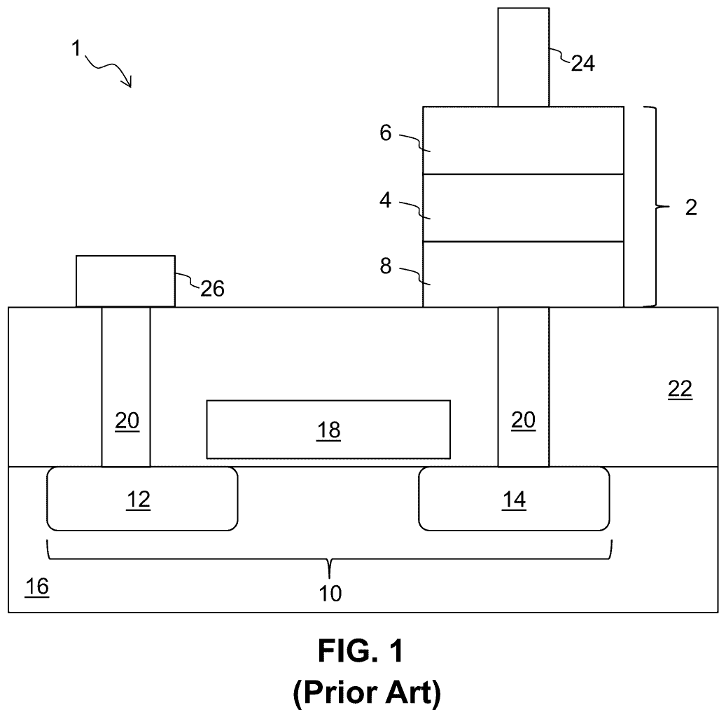

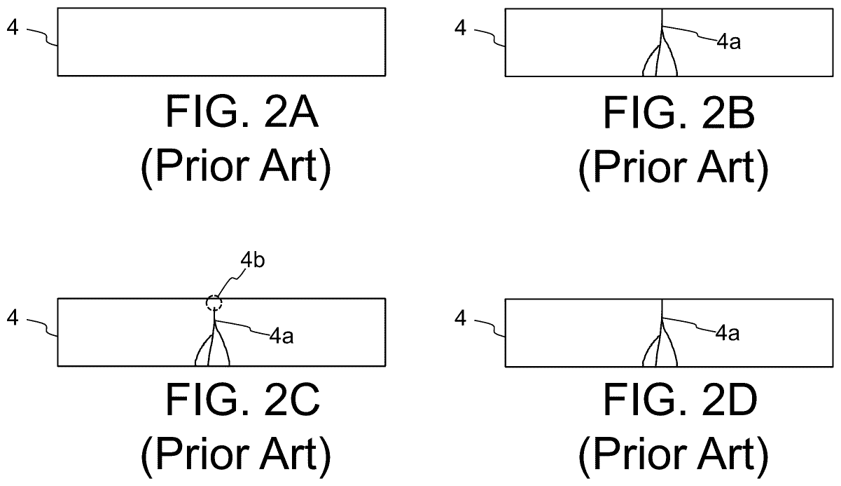

### DETAILED DESCRIPTION OF THE INVENTION

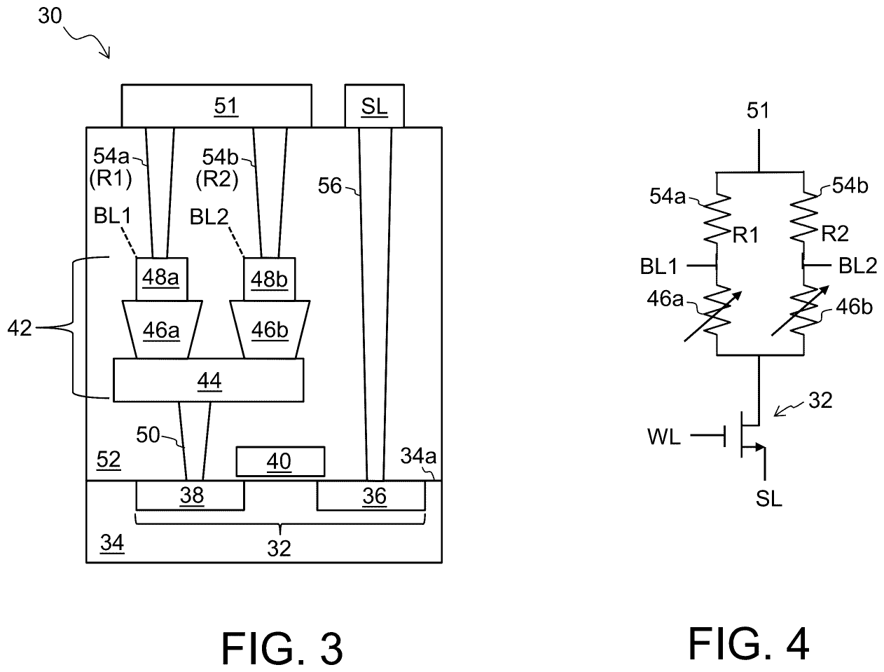

A multi-level RRAM memory cell 30, and a method of its formation, is disclosed and is shown in FIG. 3. The RRAM memory cell includes a transistor 32 formed on an upper surface 34a of a semiconductor substrate 34. The transistor 32 includes a source region 36 and drain region 38 formed in the semiconductor substrate 34, and a gate 40 formed over the semiconductor substrate 34. A resistive device 42 includes a lower electrode 44 disposed over the semiconductor substrate 34, a first block of resistive switching dielectric material 46a (also referred to herein as first RSDM block 46a) electrically connected to the lower electrode 44, a second block of resistive switching dielectric material 46b (also referred to herein as second RSDM block 46b) electrically connected to the lower electrode 44, a first upper electrode 48a electrically connected to the first RSDM block 46a, and a second upper electrode 48b electrically connected to the second RSDM block 46b.

The first and second RSDM blocks 46a, 46b can be a single layer of resistive switching oxide such as a transition metal oxide (e.g., HfO₂, Al₂O₃, TaOₓ, TiOₓ, WOₓ, VOₓ, CuOₓ). The first and second RSDM blocks 46a, 46b can also include multiple sublayers of different oxides and metals. Non-limiting examples of sublayers that can be included in the first and second RSDM blocks 46a, 46b can include a sublayer of oxygen scavenger metal such as Ti or Ta on a sublayer of a transition metal oxide (e.g., HfO₂, Al₂O₃, TaOₓ, TiOₓ, WOₓ, VOₓ, CuOₓ), or a sublayer of HfO₂ and a sublayer of Al₂O₃, or a sublayer of HfO₂ and a sublayer of Hf and a sublayer of TaOₓ, or a sublayer of HfO₂ and a sublayer of Ti and a sublayer of TiOₓ. One or more conductive filaments can be formed in the first and second RSDM blocks 46a, 46b (i.e., using the forming and reset operations discussed herein), where the first and second RSDM blocks 46a, 46b are considered to be in their low resistance state (also referred to herein as the “L state”). One or more ruptures to those filaments can be formed in the first and second RSDM blocks 46a, 46b (i.e., using the set operation discussed herein), where the first and second RSDM blocks 46a, 46b are considered to be in their high resistance state (also referred to herein as the “H state”).

The lower electrode 44 is electrically connected to the drain region 38 by an electrical contact 50. An electrical contact 51 is electrically connected to the first upper electrode 48a by a first resistive contact 54a and to the second upper electrode 48b by a second resistive contact 54b (i.e., the first resistive contact 54a is electrically connected between the first upper electrode 48a and the electrical contact 51, and the second resistive contact 54b is electrically connected between the second upper electrode 48b and the electrical contact 51). The first resistive contact 54a has an electrical resistance R1 between the first upper electrode 48a and the electrical contact 51, and the second resistive contact 54b has an electrical resistance R2 between the second upper electrode 48b and the electrical contact 51. R1 is different than R2, which can be accomplished for example by forming the first and second resistive contacts 54a, 54b of materials having different resistive properties or dimensions or both, or including one or more resistive layers (e.g., such as but not limited to Ti, W, Ta or SiCl based layer) as part of one of the first and second resistive contacts 54a, 54b that is different from or not included in the other contact. It should be noted that R1 or R2 could be as low as zero (i.e., one of the first or second resistive contacts 54a, 54b could be made of a highly conductive material such as metal while the other is not). Source region 36 is connected to a source line SL by an electrical contact 56. The RRAM memory cell 30 may be surrounded by insulation material 52.

FIG. 4 is a schematic diagram of the electrical connections to RRAM memory cell 30. A first bit line BL1 is electrically connected to the first upper electrode 48a, and a second bit line BL2 is electrically connected to the second upper electrode 48b. A word line WL is electrically connected to the gate 40 of transistor 32.

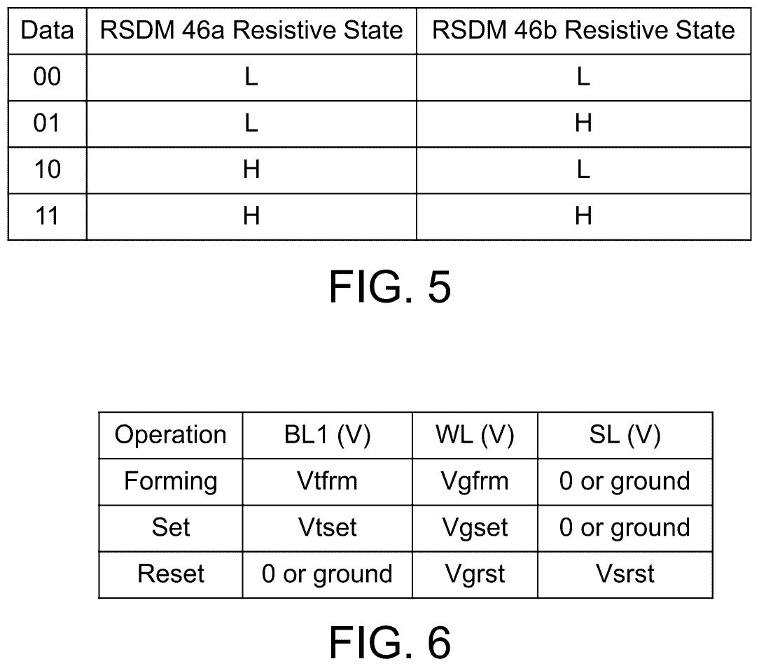

The four different possible combinations of the H state and the L state for the first and second RSDM blocks 46a, 46b can be used to represent/store 4 different data, as illustrated in FIG. 5. For example, data 00 can correspond to both first and second RSDM blocks 46a, 46b set to their L states. Data 01 can correspond to first RSDM block 46a set to its L state, and second RSDM block 46b set to its H state. Data 10 can correspond to first RSDM block 46a set to its H state, and second RSDM block 46b set to its L state. Data 11 can correspond to both first and second RSDM blocks 46a, 46b set to their H states.

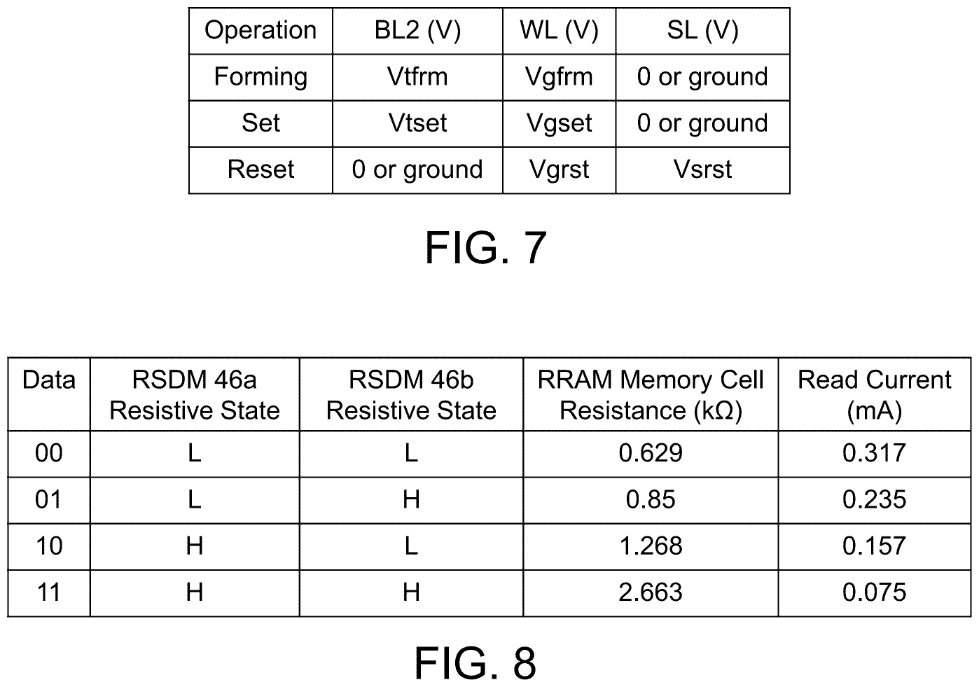

Taking first RSDM block 46a as an example, the voltages for the forming, set, and reset operations are summarized in FIG. 6. The forming operation to initially place the RSDM block 46a to its L state can include placing a filament forming voltage Vtfrm on the first bit line BL1 (and therefore on upper electrode 48a), and a positive voltage Vgfrm on the word line WL (to turn on transistor 32 so as to electrically connect lower electrode 44 to the source line SL). A zero or ground voltage can be placed on the source line SL. The voltage potential Vtfrm across RSDM block 46a will cause sufficient current to create one or more filaments therein, placing the RSDM block in its L state. The set operation to change the RSDM block 46a from its L state to its H state can include placing a rupture forming voltage Vtset on the first bit line BL1 (and therefore on upper electrode 48a), and a positive voltage Vgset on the word line WL (to turn on transistor 32 so as to electrically connect lower electrode 44 to source line SL). A zero or ground voltage can be placed on the source line SL. The voltage potential Vtset across RSDM block 46a will create one or more ruptures to the filaments, placing the RSDM block 46a in its H state. The reset operation to place the RSDM block 46a back to its L state can include placing a filament resetting voltage Vsrst on the source line SL, and a positive voltage Vgrst on the word line WL (to turn on transistor 32 so as to electrically connect lower electrode 44 to source line SL). The voltage potential Vsrst will cause current to flow in the opposite direction as in the forming operation, which will reset the one or more filaments, placing the RSDM block back in its L state. The same combinations of voltages above can be used for the forming, set and reset operations for the second RSDM block 46b, but instead applying the voltages indicated for the first bit line BL1 to the second bit line BL2, as indicated in FIG. 7. Depending on the combination of existing and desired resistance states, the forming, set or reset operations could be implemented concurrently on the first and second RSDM blocks 46a, 46b.

The read operation can include placing a read voltage Vtrd on the electrical contact 51, and a positive voltage Vgrd on the word line WL (to turn on transistor 32 so as to electrically connect lower electrode 44 to source line SL). A zero or ground voltage can be placed on the source line SL. The first and second bit lines BL1 and BL2 are allowed to have a floating voltage. The current flowing from electrical contact 51 to the source line SL is then measured, and will have a different value for each of the four possible combinations of the H state and the L state for the first and second RSDM blocks 46a, 46b. There are two current paths, flowing in parallel. The first current path (through first resistive contact 54a, upper electrode 48a, first RSDM block 46a and to lower electrode 44) will have a total resistance of R1 (the resistance of first resistive contact 54a) plus the resistance of the first RSDM block 46a (assuming the resistance of upper electrode 48a is negligible). The second current path (through second resistive contact 54b, upper electrode 48b, second RSDM block 46b and to lower electrode 44) will have a total resistance of R2 (the resistance of second resistive contact 54b) plus the resistance of the second RSDM block 46b (assuming the resistance of upper electrode 48b is negligible). The inverse of the total resistance of the memory cell over both current paths is equal to the inverse of the resistance of the first path plus the inverse of the resistance of the second path. Therefore, if R1 is different than R2, then each of four possible combinations of the H and L states will produce a unique read current relative to the other combinations, indicative of the overall programmed state of the RRAM memory cell 30.

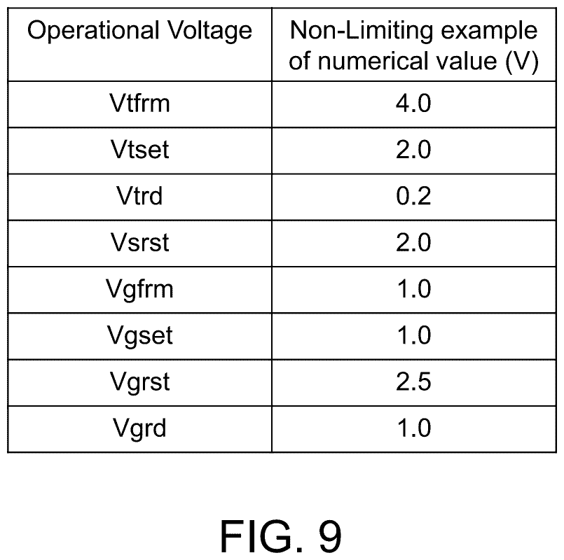

As a non-limiting example, if R1=0, R2=0.7 kΩ, the resistance of first and second RSDM blocks 46a, 46b in their L state=1 kΩ, and the resistance of first and second RSDM blocks 46a, 46b in their H state=5 kΩ, then the resulting overall resistances of the RRAM memory cell 30 and the resulting read currents in a read operation where Vtrd-0.2V are summarized in FIG. 8. It should be noted that if R1=0 (e.g., first resistive contact 54a is made of highly conductive metal), then the read voltage Vtrd could be applied to the first bit line BL1 instead of being provided by a separate line connected to electrical contact 51 (i.e., because the first bit line BL1 and electrical contact 51 are shorted together by first resistive contact 54a having zero resistance). FIG. 9 includes non-limiting numerical example of the various voltages that can be used in the formation, set, reset and read operations.

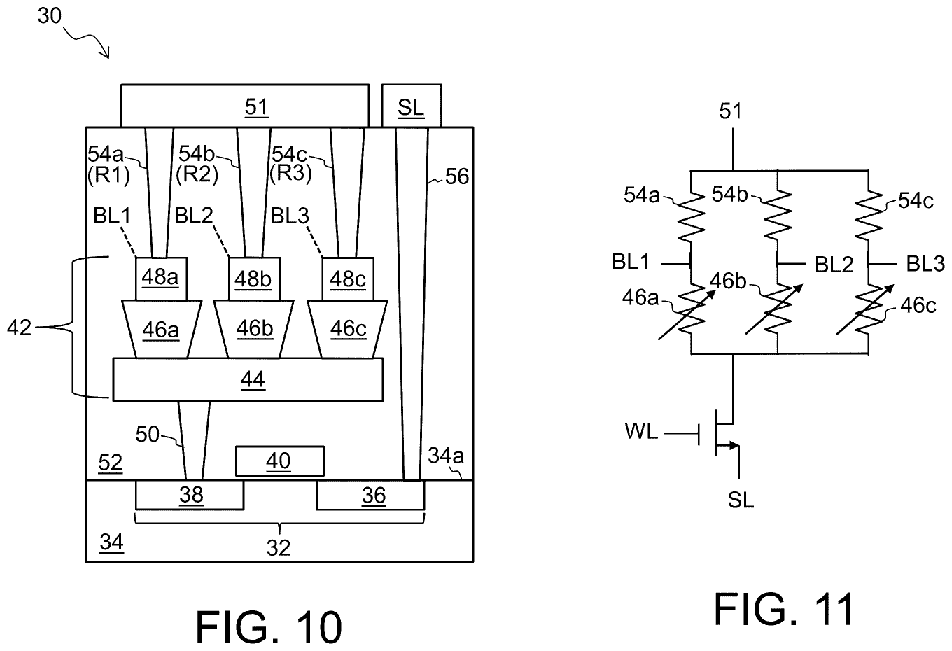

The above example is an RRAM memory cell 30 having two RSDM blocks 46a, 46b, connected in parallel to provide four possible program levels. However, more than two RSDM blocks can be provided in each RRAM memory cell 30, where the number of program levels for each RRAM memory cell 30 can be 2ⁿ, where n is the number of RSDM blocks connected in parallel in the RRAM memory cell 30. For example, FIGS. 10 and 11 illustrate a second example, where n=3, such that the RRAM memory cell 30 includes three RSDM blocks 46a, 46b, 46c, three upper electrodes 48a, 48b, 48c, three resistive contacts 54a, 54b, 54c having 3 different respective resistances, connected in parallel between electrical contact 51 and transistor 32. This memory cell configuration can provide 8 possible program levels. The number n of the number of RSDM blocks in the RRAM memory cell 30 can be any number 2 or greater.

There are many advantages of the RRAM memory cell 30 described herein. The formation of some or all of the components of resistive device 42 above the transistor 32 is an effective use of space, where multiple RSDM blocks 46a-46n can be formed in the space above transistor 32 (i.e., RSDM blocks 46a-46n are disposed (i.e., physically) between the transistor 32 and the electrical contact 51) to store multiple bits of information, which allows for more storage capacity in an array of RRAM memory cells 30 per unit area of the semiconductor substrate 34. Multiple RSDM blocks connected in parallel in each RRAM memory cell allow for multibit storage without resorting to time consuming and less reliable techniques attempting to program a single RSDM block to one or more resistive states between the H and L states.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are examples only, and should not be deemed to limit any claims. Single layers of material could be formed as multiple layers of such or similar materials, and vice versa. Lastly, the terms “forming” and “formed” as used herein shall include material deposition, material growth, or any other technique in providing the material as disclosed or claimed.

What is claimed is:

1. An RRAM memory cell comprising:
a semiconductor substrate;
a lower electrode disposed over the semiconductor substrate;
a first block of resistive switching dielectric material electrically connected to the lower electrode;
a second block of resistive switching dielectric material electrically connected to the lower electrode;
a first upper electrode electrically connected to the first block of resistive switching dielectric material;
a second upper electrode electrically connected to the second block of resistive switching dielectric material;
an electrical contact;
a first resistive contact electrically connected between the first upper electrode and the electrical contact; and
a second resistive contact electrically connected between the second upper electrode and the electrical contact;
wherein the first resistive contact has a first electrical resistance between the first upper electrode and the electrical contact, and the second resistive contact has a second electrical resistance between the second upper electrode and the electrical contact, and the first electrical resistance is different from the second electrical resistance.

2. The RRAM memory cell of claim 1, comprising:
a transistor formed on the semiconductor substrate, wherein the lower electrode is electrically connected to the transistor, and wherein the first block of resistive switching dielectric material and the second block of resistive switching dielectric material are disposed above the transistor.

3. The RRAM memory cell of claim 1, comprising:
a transistor formed on the semiconductor substrate, wherein the lower electrode is electrically connected to the transistor, and wherein the first block of resistive switching dielectric material and the second block of resistive switching dielectric material are disposed between the transistor and the electrical contact.

4. The RRAM memory cell of claim 3, comprising:
a source line electrically connected to the transistor.

5. The RRAM memory cell of claim 1, comprising:
a first bit line electrically connected to the first upper electrode; and
a second bit line electrically connected to the second upper electrode.

6. The RRAM memory cell of claim 1, comprising:
a third block of resistive switching dielectric material electrically connected to the lower electrode;
a third upper electrode electrically connected to the third block of resistive switching dielectric material; and
a third resistive contact electrically connected between the third upper electrode and the electrical contact;
wherein the third resistive contact has a third electrical resistance between the third upper electrode and the electrical contact, and the third electrical resistance is different from the first electrical resistance and the second electrical resistance.

7. The RRAM memory cell of claim 6, comprising:
a third bit line electrically connected to the third upper electrode.

8. The RRAM memory cell of claim 1, wherein the first block of resistive switching dielectric material and the second block of resistive switching dielectric material comprise one of HfO2, Al2O3, TaOx, TiOx, WOx, VOx or CuOx.

9. The RRAM memory cell of claim 1, wherein the first block of resistive switching dielectric material and the second block of resistive switching dielectric material comprise a sublayer of HfO₂ and a sublayer of Al₂O₃.

10. The RRAM memory cell of claim 1, wherein the first block of resistive switching dielectric material and the second block of resistive switching dielectric material comprise a sublayer of HfO₂, a sublayer of Hf, and a sublayer of TaOx.

11. The RRAM memory cell of claim 1, wherein the first block of resistive switching dielectric material and the second block of resistive switching dielectric material comprise a sublayer of HfO₂, a sublayer of Ti, and a sublayer of TiOx.

12. A method of forming a RRAM memory cell, comprising:
forming a transistor on a semiconductor substrate;
forming a lower electrode disposed over the semiconductor substrate;
forming a first block of resistive switching dielectric material electrically that is connected to the lower electrode;
forming a second block of resistive switching dielectric material that is electrically connected to the lower electrode;
forming a first upper electrode that is electrically connected to the first block of resistive switching dielectric material;
forming a second upper electrode that is electrically connected to the second block of resistive switching dielectric material;
forming an electrical contact;
forming a first resistive contact that is electrically connected between the first upper electrode and the electrical contact; and
forming a second resistive contact that is electrically connected between the second upper electrode and the electrical contact;
wherein the first resistive contact has a first electrical resistance between the first upper electrode and the electrical contact, and the second resistive contact has a second electrical resistance between the second upper electrode and the electrical contact, and the first electrical resistance is different from the second electrical resistance.

13. The method of claim 12, wherein the first block of resistive switching dielectric material and the second block of resistive switching dielectric material are disposed above the transistor.

14. The method of claim 12, wherein the first block of resistive switching dielectric material and the second block of resistive switching dielectric material are disposed between the transistor and the electrical contact.

15. The method of claim 12, comprising:
forming a source line that is electrically connected to the transistor.

16. The method of claim 12, comprising:
forming a first bit line that is electrically connected to the first upper electrode; and
forming a second bit line that is electrically connected to the second upper electrode.

17. The method of claim 12, comprising:
forming a third block of resistive switching dielectric material that is electrically connected to the lower electrode;
forming a third upper electrode that is electrically connected to the third block of resistive switching dielectric material; and
forming a third resistive contact that is electrically connected between the third upper electrode and the electrical contact;
wherein the third resistive contact has a third electrical resistance between the third upper electrode and the electrical contact, and the third electrical resistance is different from the first electrical resistance and the second electrical resistance.

18. The method of claim 17, comprising:
forming a third bit line that is electrically connected to the third upper electrode.

19. The method of claim 12, wherein the first block of resistive switching dielectric material and the second block of resistive switching dielectric material comprise one of HfO2, Al2O3, TaOx, TiOx, WOx, VOx or CuOx.

20. The method of claim 12, wherein the first block of resistive switching dielectric material and the second block of resistive switching dielectric material comprise a sublayer of HfO₂ and a sublayer of Al₂O₃.

21. The method of claim 12, wherein the first block of resistive switching dielectric material and the second block of resistive switching dielectric material comprise a sublayer of HfO₂, a sublayer of Hf, and a sublayer of TaOx.

22. The method of claim 12, wherein the first block of resistive switching dielectric material and the second block of resistive switching dielectric material comprise a sublayer of HfO₂, a sublayer of Ti, and a sublayer of TiOx.
